(19) United States
(12) Patent Application Publication
(10) Pub. No.: US 2026/0164993 A1
(43) Pub. Date: Jun. 11, 2026

(54) WINDOW PROTECTIVE FILM, DISPLAY DEVICE AND ELECTRONIC DEVICE

(71) Applicant: Samsung Display Co., Ltd., Yongin-Si (KR)

(72) Inventor: JINHWAN KIM, Yongin-si (KR)

(21) Appl. No.: 19/284,700

(22) Filed: Jul. 30, 2025

(30) Foreign Application Priority Data
Dec. 11, 2024 (KR) 10-2024-0183673

(51) Int. Cl. H10K 59/80

(52) U.S. Cl. CPC H10K 59/873; H10K 59/8792

(57) ABSTRACT

A window protection film having an edge including a side surface, a main surface that is connected to the edge and is in a plane that makes an angle with the side surface, and a light blocking pattern on the main surface, the light blocking pattern extending along the edge and flush with the side surface. The light blocking pattern has a non-transmissive area and a transmissive area, and may be used for visual alignment of the window and the window protection film.

### CROSS-REFERENCE TO RELATED APPLICATION(S)

This application claims priority, under 35 USC § 119, to Korean Patent Application No. 10-2024-0183673 filed on Dec. 11, 2024 in the Korean Intellectual Property Office (KIPO), the entire disclosure of which is incorporated by reference herein.

### BACKGROUND

### 1. Field

Embodiments relate to a window protection film. More specifically, embodiments relate to a window protection film that protects a window for a display device, a display device including the window protection film, and an electronic device including the display device.

### 2. Description of the Related Art

Recently, a flexible display device that can be transformed into various forms has been developed. Unlike a flat panel display device, the flexible display device can be folded, bent, or rolled like paper. The flexible display device is easy to carry and can improve user convenience.

### SUMMARY

The disclosure pertains to a window protection firm that protects a window.

the disclosure pertains to a display device including the window protection film.

The disclosure pertains to an electronic device including the display device.

A window protection film according to an embodiment of the present disclosure includes an edge including a side surface, a main surface that is connected to the edge and is in a plane that makes an angle with the side surface, and a light blocking pattern on the main surface, the light blocking pattern extending along the edge and flush with the side surface, the light blocking pattern having a non-transmissive area and a transmissive area.

The main surface may include a first side, a second side facing the first side, a third side connected to each of the first side and the second side, and a fourth side facing the third side and connected to each of the first side and the second side.

The transmissive area may include a first transmissive area, a second transmissive area, a third transmissive area, and a fourth transmissive area, wherein the first transmissive area is disposed along the first side and flush with the side surface, the second transmissive area is disposed along the second side and flush with the side surface, the third transmissive area is disposed along the third side and flush with the side surface, and the fourth transmissive area is disposed along the fourth side and flush with the side surface.

The first transmissive area and the second transmissive area may face each other.

The third transmissive area and the fourth transmissive area may face each other.

A display device according to an embodiment of the present disclosure includes a display panel including a plurality of pixels, a window arranged on the display panel, and a window protection film arranged on the window. The window protection film includes a first edge having a side surface, a main surface that is connected to the first edge and is in a plane that forms an angle with the side surface, and a light blocking pattern on the main surface, the light blocking pattern extending along the first edge and flush with the side surface, the light blocking pattern having a non-transmissive area and a transmissive area.

The first edge of the window protection film may extend beyond a second edge of the window by a first gap.

The main surface may include a first side, a second side facing the first side, a third side connected to each of the first side and the second side, and a fourth side facing the third side and connected to each of the first side and the second side.

The transmissive area may include a first transmissive area disposed along the first side and flush with the side surface, a second transmissive area disposed along the second side and flush with the side surface, a third transmissive area disposed along the third side and flush with the side surface, and a fourth transmissive area disposed along the fourth side and flush with the side surface.

Each of the first transmissive area, the second transmissive area, the third transmissive area, and the fourth transmissive area may have a width that is greater than the first gap measured from the first edge.

The second edge of the window may be visible through each of the first transmissive area, the second transmissive area, the third transmissive area, and the fourth transmissive area.

In an embodiment, the first transmissive area and the second transmissive area may face each other.

In an embodiment, the first transmissive area may be at a midpoint of the first side, and the second transmissive area may be at a midpoint of the second side.

The third transmissive area and the fourth transmissive area may face each other.

The third transmissive area may be at a midpoint of the third side, and the fourth transmissive area may be at a midpoint of the fourth side.

The window may include ultra-thin glass (UTG).

In an embodiment, the display device may include a folding area having flexibility and a non-folding area adjacent to at least one side of the folding area.

An electronic device according to an embodiment of the present disclosure includes a display device including a display panel including a plurality of pixels, a window arranged on the display panel, and a window protection film arranged on the window, and a processor that controls the display device. The window protection film includes a first edge including a side surface, a main surface that is connected to the fist edge and is in a plane that makes an angle with the side surface, and a light blocking pattern on the main surface, the light blocking pattern extending along the first edge and flush with the side surface, the light blocking pattern having a non-transmissive area and a transmissive area.

The first edge of the window protective film may extend beyond a second edge of the window by a first gap, the transmissive area of the light blocking pattern may be flush with the side surface and have a width that is greater than the first gap measured from the first edge.

In an embodiment, the second edge of the window may be visible through the transmissive area.

In a display device according to embodiments of the present disclosure, the display device may include a window protection film arranged on a window and including a light blocking pattern. The light blocking pattern may extend along an edge of the window protection film, and at least a portion of the light blocking pattern may be recessed on each surface of the window protection film to define a transmissive area. Since an alignment of the window with respect to the window protection film may be visually confirmed through the transmissive area, display quality of the display device may be improved.

### BRIEF DESCRIPTION OF THE DRAWINGS

FIG. 1 is a plan view illustrating a display device according to an embodiment of the present disclosure.

FIGS. 2 and 3 are cross-sectional views illustrating a folding state of the display device of FIG. 1.

FIG. 4 is a cross-sectional view illustrating the display device of FIG. 1.

FIG. 5 is a cross-sectional view illustrating a display panel of FIG. 4.

FIG. 6 is a plan view illustrating a window protection film of FIG. 4.

FIGS. 7 and 8 are plan views illustrating a window and a window protection film of FIG. 4.

FIG. 9 is a block diagram illustrating an electronic device according to an embodiment of the present disclosure.

FIG. 10 is a diagram illustrating an example in which the electronic device of FIG. 9 is implemented as a smartphone.

### DETAILED DESCRIPTION OF THE EMBODIMENTS

Hereinafter, embodiments of the present disclosure will be described in more detail with reference to the accompanying drawings. The same reference numerals are used for the same components in the drawings, and redundant descriptions of the same components will be omitted.

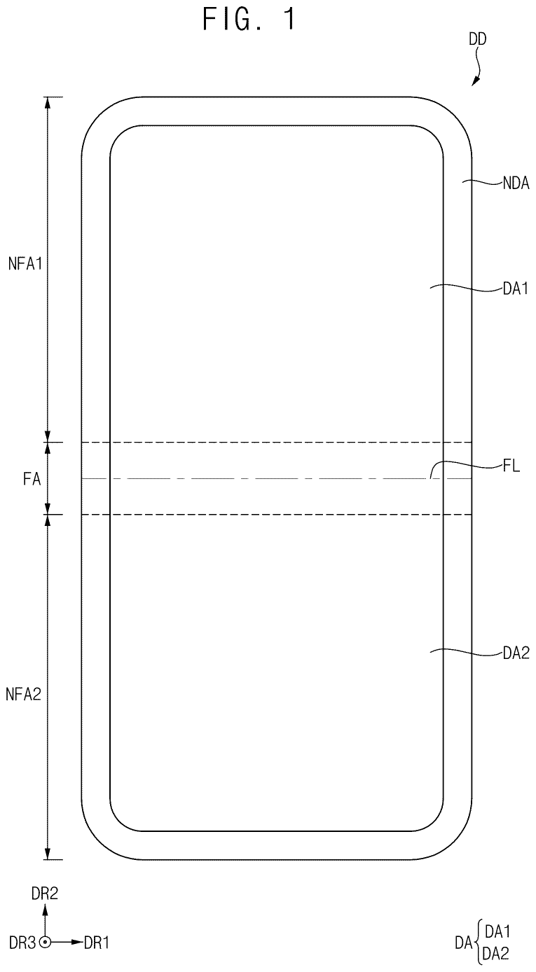

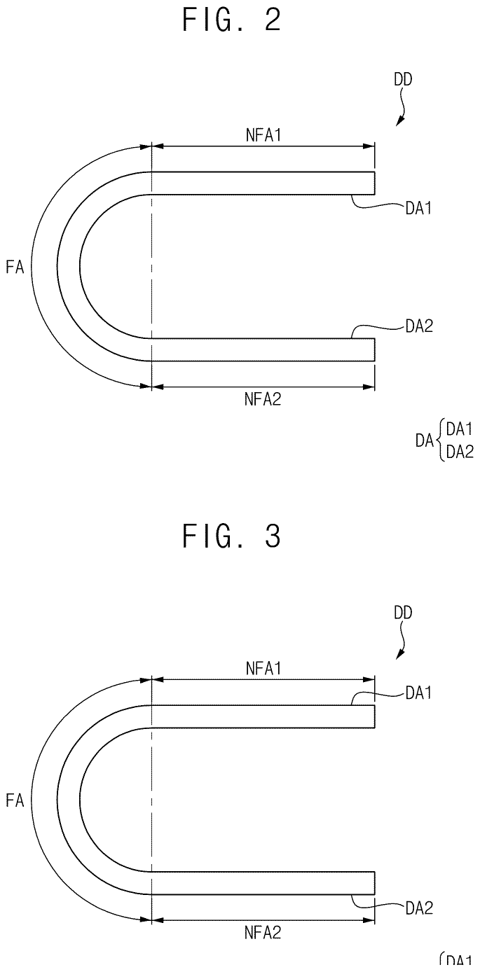

FIG. 1 is a plan view illustrating a display device according to an embodiment of the present disclosure. FIGS. 2 and 3 are cross-sectional views illustrating a folding state of the display device of FIG. 1.

Referring to FIGS. 1, 2, and 3, a display device DD may include a display area DA and a non-display area NDA. The display area DA may be an area capable of generating light to display an image. The non-display area NDA may be an area that does not display an image. The non-display area NDA may be located around the display area DA. For example, the non-display area NDA may surround the display area DA in a plan view.

At least a portion of the display device DD may have flexibility, and may be folded in an area having flexibility. The display device DD may include the folding area FA that may be folded or unfolded by an external force and a non-folding area NFA1 and NFA2 that may not be folded. The non-folding area NFA1 and NFA2 may be adjacent (or near) to at least one side of the folding area FA. For example, the folding area FA may be located between a first non-folding area NFA1 and a second non-folding area NFA2.

Here, the “non-folding” area may include not only a rigid area without flexibility, but also an area that is much less flexible than the folding area FA and is not folded during normal usage.

For example, the folding area FA may have a folding line FL. The folding area FA may extend along a first direction DR1. The folding area FA may be folded with respect to the folding line FL, so that the display device DD may be folded.

The display area DA may be conceptually divided into a first display area DA1 and a second display area DA2 by the folding line FL. The first display area DA1 and the second display area DA2 may be adjacent in a second direction DR2 intersecting the first direction DR1. The first display area DA1 and the second display area DA2 may be continuously connected to each other across the folding line FL to form substantially one display area DA.

For example, as illustrated in FIG. 2, when the display area DA is folded along the folding line FL, the display device DD may have an in-folding structure in which the first display area DA1 and the second display area DA2 face each other. In another example, as illustrated in FIG. 3, when the display area DA is folded along the folding line FL, the display device DD may have an out-folding structure in which the first display area DA1 and the second display area DA2 are arranged on outer surfaces in a folded state.

Although FIG. 1 illustrates that the display device DD includes one folding area FA, the present disclosure is not limited thereto. For example, the display device DD may include a plurality of folding areas, and may be folded along multiple folding lines (one at a time or at the same time) or may implement a rollable display device.

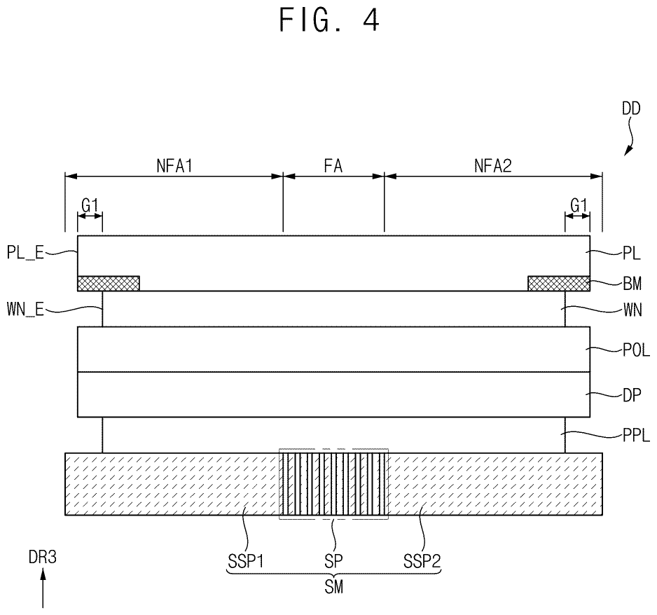

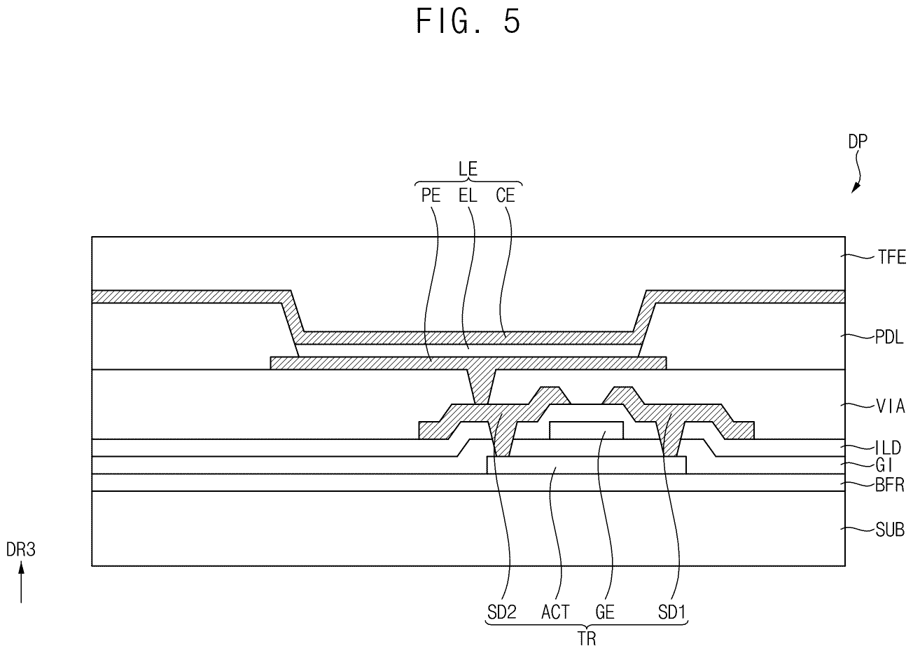

FIG. 4 is a cross-sectional view illustrating the display device of FIG. 1. FIG. 5 is a cross-sectional view illustrating a display panel of FIG. 4.

Referring to FIGS. 1 and 4, the display device DD may include a display panel DP, a polarizing layer POL, a window WN, a window protection film PL, a panel protection film PPL, and a support plate SM.

The display panel DP may include a plurality of pixels, each of which emit light. The pixels may be arranged in the display area DA. For example, the pixels may be arranged in a matrix form along the first and second directions DR1 and DR2. Light emitted from each of the pixels may be combined to generate the image in the display area DA. For example, the image may be displayed in a third direction DR3 intersecting each of the first and second directions DR1 and DR2 in the display area DA.

Hereinafter, the display panel DP will be described with reference to FIG. 5. Referring to FIG. 5, the display panel DP may include a substrate SUB, a buffer layer BFR, a transistor TR, a gate insulating layer GI, an interlayer insulating layer ILD, a via insulating layer VIA, a light emitting element LE, a pixel defining layer PDL, and an encapsulation layer TFE. The transistor TR may include an active pattern ACT, a gate electrode GE, a first electrode SD1, and a second electrode SD2, and the light emitting element LE may include a pixel electrode PE, a light emitting layer EL, and a common electrode CE.

The substrate SUB may include a transparent material or an opaque material. For example, the substrate SUB may include plastic, glass, quartz, silicon, or the like. These may be used alone or in combination with each other. In an embodiment, the substrate SUB may include plastic and may have flexibility. The display panel DP may be a display panel having flexibility.

The buffer layer BFR may be arranged on the substrate SUB. The buffer layer BFR may prevent metal atoms, impurities, or the like from diffusing into the transistor TR. The buffer layer BFR may include an inorganic material such as silicon oxide (SiOₓ), silicon nitride (SiNₓ), silicon oxynitride (SiOₓN_{y}), or the like. These may be used alone or in combination with each other.

The active pattern ACT may be arranged on the buffer layer BFR. The active pattern ACT may include a source area, a drain area, and a channel area between the source area and the drain area. The active pattern ACT may include a silicon semiconductor material, an oxide semiconductor material, or the like. Examples of the silicon semiconductor material may include amorphous silicon, polycrystalline silicon, or the like. Examples of the oxide semiconductor material may include indium gallium zinc oxide (IGZO), indium tin zinc oxide (ITZO), or the like. These may be used alone or in combination with each other.

The gate insulating layer GI may be arranged on the active pattern ACT and may cover at least a portion of the active pattern ACT. The gate insulating layer GI may include an inorganic material such as silicon oxide, silicon nitride, silicon oxynitride, or the like. These may be used alone or in combination with each other.

The gate electrode GE may be arranged on the gate insulating layer GI. The gate electrode GE may overlap the channel area of the active pattern ACT in a plan view. The gate electrode GE may include a metal, an alloy, a conductive metal oxide, a conductive metal nitride, a transparent conductive material, or the like. These may be used alone or in combination with each other.

The interlayer insulating layer ILD may be arranged on the gate electrode GE and may cover the gate electrode GE. The interlayer insulating layer ILD may include an inorganic material such as silicon oxide, silicon nitride, silicon oxynitride, or the like. These may be used alone or in combination with each other.

The first electrode SD1 and the second electrode SD2 may be arranged on the interlayer insulating layer ILD. The first electrode SD1 may be connected to the source area of the active pattern ACT through a first contact hole penetrating a lower insulating layer (e.g., the gate insulating layer GI and the interlayer insulating layer ILD). The second electrode SD2 may be connected to the drain area of the active pattern ACT through a second contact hole penetrating a lower insulating layer (e.g., the gate insulating layer GI and the interlayer insulating layer ILD). The first and second electrodes SD1 and SD2 may include a metal, an alloy, a conductive metal oxide, a conductive metal nitride, a transparent conductive material, or the like. These may be used alone or in combination with each other.

Accordingly, the transistor TR including the active pattern ACT, the gate electrode GE, the first electrode SD1, and the second electrode SD2 may be arranged on the substrate SUB.

The via insulating layer VIA may be arranged on the first and second electrodes SD1 and SD2 and may cover the first and second electrodes SD1 and SD2. The via insulating layer VIA may include an organic material such as phenol resin, acrylic resin, polyimide resin, polyamide resin, siloxane resin, epoxy resin, or the like. These may be used alone or in combination with each other.

The pixel electrode PE may be arranged on the via insulating layer VIA. The pixel electrode PE may be electrically connected to the transistor TR. For example, the pixel electrode PE may be connected to the second electrode SD2 (or the first electrode SD1) through a contact hole penetrating through a lower insulating layer (e.g., the via insulating layer VIA). The pixel electrode PE may include a metal, an alloy, a conductive metal oxide, a conductive metal nitride, a transparent conductive material, or the like. These may be used alone or in combination with each other.

The pixel defining layer PDL may be arranged on the via insulating layer VIA. The pixel defining layer PDL may cover an edge of the pixel electrode PE and may define an opening exposing at least a portion of an upper surface of the pixel electrode PE. The pixel defining layer PDL may include an organic material such as polyimide resin, epoxy resin, siloxane resin, or the like. These may be used alone or in combination with each other.

The light emitting layer EL may be arranged on the pixel electrode PE. The light emitting layer EL may be arranged on the upper surface of the pixel electrode PE exposed by the pixel defining layer PDL. The light emitting layer EL may include a material that emits light of a selected color. For example, the light emitting layer EL may include a material that emits light of a red wavelength band, light of a green wavelength band, or light of a blue wavelength band, but the present disclosure is not limited thereto.

The common electrode CE may be arranged on the pixel defining layer PDL and the light emitting layer EL. The common electrode CE may include a metal, an alloy, a conductive metal oxide, a conductive metal nitride, a transparent conductive material, or the like. These may be used alone or in combination with each other.

Accordingly, the light emitting element LE including the pixel electrode PE, the light emitting layer EL, and the common electrode CE may be arranged on the substrate SUB. The light emitting element LE may be electrically connected to the transistor TR. The light emitting element LE may generate light corresponding to a driving current provided from the transistor TR. The transistor TR and the light emitting element LE may correspond to each of the pixels.

The encapsulation layer TFE may be arranged on the common electrode CE. The encapsulation layer TFE may protect the light emitting element LE from external moisture, oxygen, or the like. The encapsulation layer TFE may include at least one inorganic layer and at least one organic layer. In addition, although not illustrated in the drawing, various functional layers such as a touch sensing layer, a color filter layer, a condensing layer, or the like may be additionally arranged on the encapsulation layer TFE.

Referring back to FIGS. 1 and 4, the polarizing layer POL may be arranged on the display panel DP. The polarizing layer POL may reduce reflectance of external light incident on the display device DD. For example, the polarizing layer POL may prevent external light incident through a front surface of the display device DD from being reflected by components included in the display panel DP and being visually recognized from outside. In an embodiment, the polarizing layer POL may be omitted.

For example, the polarizing layer POL may include a phase retarder or a polarizer. The phase retarder may be a film type or a liquid crystal coating type, and may include a λ/2 phase retarder or a λ/4 phase retarder. The polarizer may also be a film type or a liquid crystal coating type. For example, the phase retarder and the polarizer may be a single polarizing film. The polarizing layer POL may further include a protective film arranged above or below the polarizing film.

The window WN may be arranged on the polarizing layer POL. The window WN may be optically transparent. The window WN may include a material having a relatively high transmittance and may transmit light generated from the display panel DP. The window WN may protect the display panel DP from external impact. For example, the window WN may include glass, plastic, sapphire, or the like.

In an embodiment, the window WN may include ultra-thin glass (UTG). The ultra-thin glass may be strengthened to have a selected stress profile therein. The ultra-thin glass may better prevent cracks from occurring, cracks from propagating, breakage, or the like caused by external impact than before strengthening. The ultra-thin glass may have various stresses in each area through a strengthening process.

For example, the ultra-thin glass of the window WN may be a thin film that has been chemically strengthened. However, the present disclosure is not limited thereto, and the ultra-thin glass of the window WN may be a thin film glass that has been thermally strengthened.

When a glass is formed of an ultra-thin film or a thin film, the glass may have flexibility and thus may be bent, folded, or rolled. For example, the window WN may include glass such as soda lime glass, alkali aluminosilicate glass, borosilicate glass, lithium alumina silicate glass, or the like. These may be used alone or in combination with each other. However, the present disclosure is not limited thereto, and the window WN may include various types of glass.

The window protection film PL may be arranged on the window WN. The window protection film PL may protect the window WN from external impact. In addition, the window protection film PL may prevent or minimize scratches on an upper surface of the window WN. The window protection film PL may perform at least one of functions of preventing scattering, absorbing impact, preventing imprints, preventing fingerprints, and preventing glare of the window WN.

The window protection film PL may include a polymer resin. For example, the window protection film PL may include epoxy resin, polyurethane resin, polyester resin, polyethylene terephthalate resin, polyethylene naphthalate resin, polyimide resin, polyarylate resin, polycarbonate resin, polymethyl methacrylate resin, ethyl vinyl acetate resin, polyamide resin, or the like. These may be used alone or in combination with each other. The window protection film PL is transparent or transmissive. As shown in FIG. 4, the window protection film PL has a first edge PL_E, which includes a side surface.

The window protection film PL may include a light blocking pattern BM. The light blocking pattern BM may be arranged (e.g., printed) on a main surface of the window protection film PL. The main surface is connected to the first edge PL_E of the window protection film PL, and makes an angle with respect to the side surface of the first edge PL_E. For example, the main surface may be a surface that is facing the window WN of the window protection film PL). The light blocking pattern BM may overlap the non-display area NDA in a plan view. For example, the light blocking pattern BM may extend along a first edge PL_E of the window protection film PL. The light blocking pattern BM may include a light blocking material and may have a selected color. For example, the light blocking pattern BM may include an organic material having a black color. The light blocking pattern BM may cover the non-display area NDA so that components arranged in the non-display area NDA are not visible from outside.

The window protection film PL may cover the window WN and may extend beyond the edge of the window WN. That is, the first edge PL_E of the window protection film PL may extend beyond a second edge WN_E of the window WN. A first gap G1 may be defined between the first edge PL_E of the window protection film PL and the second edge WN_E of the window WN, as distance measured from the respective side surface in the first or second direction DR1/DR2.

The panel protection film PPL may be arranged below the display panel DP. The panel protection film PPL may protect the display panel DP from external impact. The panel protection film PPL may include a polymer resin. For example, the panel protection film PPL may include polyethylene terephthalate resin, but the present disclosure is not limited thereto.

The support plate SM may be arranged below the panel protection film PPL. The support plate SM may support the display panel DP. In addition, the support plate SM may assist in folding the display panel DP. In addition, the support plate SM may prevent foreign substances from entering the display panel DP from outside. In addition, the support plate SM may dissipate or disperse heat generated in the display panel DP.

The support plate SM may be more rigid than the display panel DP. Therefore, the support plate SM may prevent deformation of the display panel DP due to external force.

In an embodiment, the support plate SM may include a metal or an alloy. For example, the support plate SM may include stainless steel (SUS), titanium, aluminum, magnesium, a titanium alloy, an aluminum alloy, a magnesium alloy, or the like. In an embodiment, the support plate SM may include glass or plastic. For example, the support plate SM may include carbon fiber reinforced plastic (CFRP), glass fiber reinforced plastic (GFRP), or the like. However, the present disclosure is not limited thereto, and the support plate SM may include various materials.

The support plate SM may include a first support portion SSP1, a second support portion SSP2, and a folding portion SP. The folding portion SP may be located between the first support portion SSP1 and the second support portion SSP2. In a plan view, the folding portion SP may overlap the folding area FA, the first support portion SSP1 may overlap the first non-folding area NFA1, and the second support portion SSP2 may overlap the second non-folding area NFA2. At least one opening may be defined in the folding portion SP, and the folding portion SP may allow folding and unfolding of the display device DD, for example by stretch or sliding of parts. Accordingly, the first and second support portions SSP1 and SSP2 may support a portion of the display panel DP overlapping the first and second non-folding areas NFA1 and NFA2 in a plan view, and the folding portion SP may help the display panel DP to be folded.

Although FIG. 4 illustrates that the support plate SM includes one folding portion SP, the present disclosure is not limited thereto, and the support plate SM may include a plurality of folding portions. The folding portions may be bendable, stretchable, slidable, or otherwise movable to allow repeated folding and unfolding.

As described above, since the display device DD may be folded or unfolded, the display panel DP, the polarizing layer POL, the window WN, the window protection film PL, the panel protection film PPL, and the support plate SM may each have flexibility.

The display device DD may further include a lower component arranged below the support plate SM. For example, the lower component may include at least one of an elastic member, a metal plate, a heat dissipation member, and a digitizer, but the present disclosure is not limited thereto.

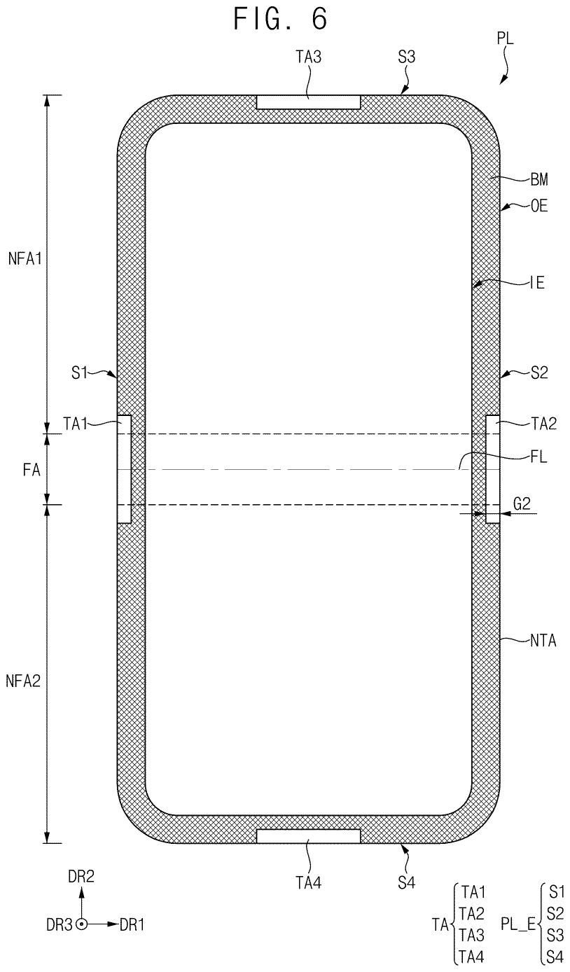

FIG. 6 is a plan view illustrating a window protection film of FIG. 4. FIG. 6 is the plan view from a front surface of the window protection film PL. Due to the window protection PL being transmissive, the light blocking pattern BM is visible from the front surface even in cases where the light blocking pattern BM is on the bottom surface of the window protection PL, as in the example of FIG. 4. In the example of FIG. 4, there is a recessed portion formed along the edge of the window protection film PL, and the light blocking pattern BM is disposed on the main surface of the recessed portion. However, FIG. 4 is just an example and other ways to deposit the light blocking pattern BM may be used with or without a recess in the window protection film PL. For example, the light blocking pattern BM may be printed or coated on a flat main surface of the window protection film PL that extends across the entire width of the window protection film PL. In the embodiment of FIG. 6, the light blocking pattern BM continuously goes around the edge of the window protection film PL.

Referring to FIG. 6, the window protection film PL may include the light blocking pattern BM. The light blocking pattern BM may extend along the first edge PL_E of the window protection film PL. The light blocking pattern BM may include a transmissive area TA (characterized by an absence of light-blocking material) and a non-transmissive area NTA (where there is light-blocking material), as indicated in FIG. 6. The light blocking pattern BM has an outer edge OE and an inner edge IE, and the distance between the outer edge OE and the inner edge IE (herein referred to as the “width of the light blocking pattern BM” measured in the first direction DR1 or the second direction DR2 depending on the side) may be constant along one side except for where there is a transmissive area TA. In some embodiments, the width of the light blocking pattern BM may be constant along all the sides except for where there are transmissive areas TA. Furthermore, the outer edge OE of the light blocking pattern BM may be flush with, or coincide with, the first edge PL_E of the window protection film PL except where there is a transmissive area TA.

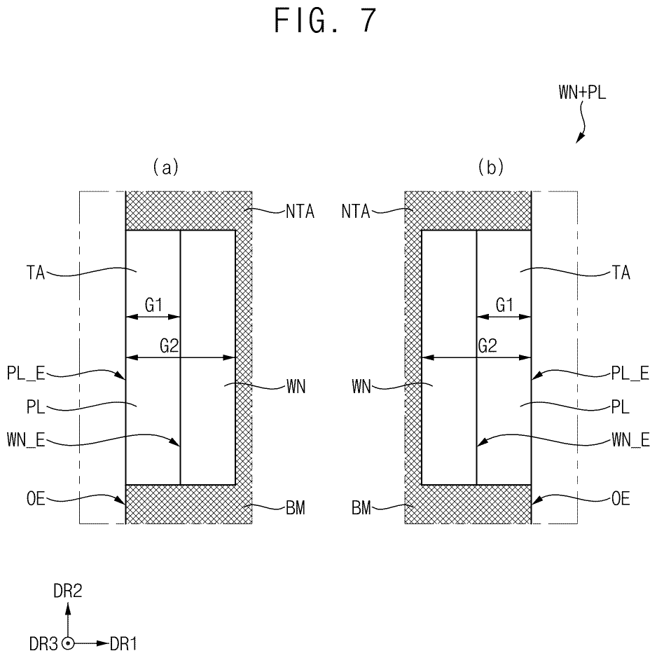

The non-transmissive area NTA may be an area in which the light blocking pattern BM is arranged (e.g., printed) along the first edge PL_E of the window protection film PL. The first edge PL_E of the window protection film PL includes the outer side surface of the window protection film PL. The light blocking pattern BM may be positioned along the edge of the window protection film PL such that it is flush with the side surface of the window protection film PL. As used herein, two elements being “flush” with each other means they form a plane, with neither element extending beyond the other. FIG. 4 and FIG. 7, for example, illustrate that the light blocking pattern BM (either the non-transmissive area NTA or the transmissive area TA) is flush with the side surface of the edge of the window protection film PL. The non-transmissive area NTA may be an area that does not transmit light. The non-transmissive area NTA may have a lower light transmittance than the transmissive area TA.

The transmissive area TA may be an area in which the light blocking pattern BM is absent. In the embodiment of FIG. 6, there is a transmissive area TA along the edge of the window protection film PL, on each side of the main surface. Although the transmissive area TA in the embodiment of FIG. 6 is formed near a midpoint of each of the sides, this is not a limitation of the disclosure. The transmissive area TA may be formed such that it is flush with the edge—part of it coincides with the first edge PL_E of the window protection film PL. The transmissive area TA may transmit incident light. The transmissive area TA may be an optically transparent area. The transmissive area TA may be an area where the light blocking pattern BM is absent. For example, the width of the transmissive area TA may have a distance that is shown as a second gap G2 in FIG. 7. As illustrated in FIG. 7, the second gap G2 is greater than the first gap G1 but not greater than the thickness of the light blocking pattern BM. In some embodiments, the second gap G2 may be the same as the thickness of the light blocking pattern BM. In some embodiments, the second gap of the different transmissive areas fall within a range that is greater than the first gap G1 and no greater than the thickness of the light blocking pattern BM.

The first edge PL_E of the window protection film PL may include a side surface. In the embodiment shown, the first edge PL_E may include a first side S1, a second side S2, a third side S3, and a fourth side S4, each of which is connected to the side surface of the window protection film PL. The first side S1 and the second side S2 may face each other, and the third side S3 and the fourth side S4 may be connected to the first side S1 and the second side S2 and face each other. For example, each of the first side S1 and the second side S2 may extend in the second direction DR2, and each of the third side S3 and the fourth side S4 may extend in the first direction DR1.

For example, referring to FIG. 6, the first side S1 may be defined as a left side of the window protection film PL, the second side S2 may be defined as a right side of the window protection film PL, the third side S3 may be defined as the top side of the window protection film PL, and the fourth side S4 may be defined as the bottom side of the window protection film PL.

There may be a plurality of transmissive areas TA. In an embodiment, the transmissive area TA may be disposed along each side of the first edge PL_E of the window protection film PL. For example, the transmissive area TA may include a first transmissive area TA1, a second transmissive area TA2, a third transmissive area TA3, and a fourth transmissive area TA4. The first transmissive area TA1 may be disposed along the first side S1, the second transmissive area TA2 may be disposed along the second side S2, and the third transmissive area TA3 may be disposed along the third side S3, and the fourth transmissive area TA4 may be disposed along the fourth side S4.

The first transmissive area TA1 may be an area of the light blocking pattern BM where the light-blocking material is recessed from the outer edge OE (i.e., the first edge PL_E) toward the inner edge IE by the second gap G2 along the first side S1. The second transmissive area TA2 may be an area of the light blocking pattern BM where the light-blocking material is recessed from the outer edge OE (i.e., the first edge PL_E) toward the inner edge IE by the second gap G2 along the second side S2. The third transmissive area TA3 may be an area of the light blocking pattern BM where the light-blocking material is recessed from the outer edge OE (i.e., the first edge PL_E) toward the inner edge IE by the second gap G2 along the third side S3. The fourth transmissive area TA4 may be an area of the light blocking pattern BM where the light-blocking material is recessed from the outer edge OE (i.e., the first edge PL_E) toward the inner edge IE by the second gap G2 along the fourth side S4.

For example, the first transmissive area TA1 and the second transmissive area TA2 may face each other in the first direction DR1. The third transmissive area TA3 and the fourth transmissive area TA4 may face each other in the second direction DR2.

Each of the first and second transmissive areas TA1 and TA2 may overlap the folding area FA in a plan view. For example, the first, second, third, and fourth transmissive areas TA1, TA2, TA3, and TA4 may be respectively defined at a midpoint of the first, second, third, and fourth sides S1, S2, S3, and S4 in a plan view. However, the present disclosure is not limited thereto, and an area in which the first, second, third, and fourth transmissive areas TA1, TA2, TA3 and TA4 are disposed may be changed.

Although FIG. 6 illustrates that one transmissive area is defined along each side of the window protection film PL, the present disclosure is not limited thereto. For example, a plurality of transmissive areas may be defined on each side of the window protection film PL.

FIGS. 7 and 8 are plan views illustrating a window and a window protection film of FIG. 4. FIGS. 7 and 8 may be plan views illustrating some areas of the window WN and the window protection film PL arranged on the window WN.

For example, referring to FIG. 6, depiction (a) of FIG. 7 may be a plan view illustrating the first transmissive area TA1 of the window protection film PL and the window WN, and depiction (b) of FIG. 7 may be a plan view illustrating the second transmissive area TA2 of the window protection film PL and the window WN. For example, referring to FIG. 6, depiction (a) of FIG. 8 may be a plan view illustrating the third transmissive area TA3 of the window protection film PL and the window WN, and depiction (b) of FIG. 8 may be a plan view illustrating the fourth transmissive area TA4 of the window protection film PL and the window WN.

Referring to FIGS. 6, 7, and 8, the window protection film PL may be arranged on the window WN. For example, the window protection film PL may be adjacent to the window WN in the third direction DR3.

The second edge WN_E of the window WN and the first edge PL_E of the window protection film PL may be spaced apart by the first gap G1. That is, the first edge PL_E of the window protection film PL may extend beyond the second edge WN_E of the window WN by the first gap G1.

The window protection film PL may include the light blocking pattern BM. The light blocking pattern BM may define the non-transmissive area NTA in which the light blocking pattern BM is arranged and the transmissive area TA in which the light blocking pattern BM is not arranged at the first edge PL_E of the window protection film PL. The light blocking pattern BM may be recessed from the outer edge OE of the light blocking pattern BM to the inner edge IE of the light blocking pattern BM by the second gap G2 in the transmissive area TA. That is, the transmissive area TA of the second gap G2 in which the light blocking pattern BM is not arranged on each surface of the first edge PL_E of the window protection film PL may be defined.

The second gap G2 may be greater than the first gap G1. Since a gap between the first edge PL_E of the window protection film PL and the second edge WN_E of the window WN is the first gap G1 and a gap between the first edge PL_E of the window protection film PL and the light blocking pattern BM in the transmissive area TA is the second gap G2, the second edge WN_E of the window WN may be visible through the transmissive area TA (e.g., each of the first, second, third, and fourth transmissive areas TA1, TA2, TA3, and TA4 of FIG. 6).

In contrast, since the light blocking pattern BM has a selected color, the second edge WN_E of the window WN may not be visible in the non-transmissive area NTA in which the light blocking pattern BM is arranged. That is, in an embodiment, an alignment (or position) of the window WN may be visually confirmed through the transmissive area TA in which the light blocking pattern BM is not printed.

Since the window protection film PL extends beyond the window WN, the window protection film PL may be attached to a lower component of the window WN (e.g., the polarizing layer POL of FIG. 4) during a manufacturing process of the display device DD. For example, the window protection film PL may be attached to the lower component by an adhesive that attaches the window WN and the window protection film PL and an adhesive that attaches the lower component and the window WN, and the window protection film PL may be pressed in an area in which the window protection film PL extends beyond the edge of the window WN.

In this case, when the window protection film PL extends beyond the edge of the window WN, pressing of the window protection film PL may be visually recognized from outside. Therefore, in an embodiment, by forming the transmissive area TA where the light blocking pattern BM is not arranged (i.e., not printed) on the first edge PL_E of the window protection film PL, an alignment of the window WN may be visually confirmed, and the first gap G1 may be controlled.

For example, as illustrated in depiction (a) of FIG. 7, a left alignment of the window WN or the first gap G1 by which the window protection film PL extends beyond the second edge WN_E may be confirmed (or controlled) in the transmissive area TA. The transmissive area TA is formed by the light blocking pattern BM being recessed from the first edge PL_E of the window protection film PL. For example, as illustrated in depiction (b) of FIG. 7, a right alignment of the window WN or the first gap G1 by which the window protection film PL extends beyond the second edge WN_E may be confirmed (or controlled) in the transmissive area TA, which is formed by the light blocking pattern BM being recessed from the first edge PL_E of the window protection film PL.

That is, as illustrated in FIGS. 6 and 7, the alignment of the window WN along an axis in the first direction DR1 (e.g., x-axis) or the extension distance of the window protection film PL along an axis in the first direction DR1 (e.g., x-axis) may be visually confirmed through the left and right transmissive areas TA1 and TA2.

For example, as illustrated in depiction (a) of FIG. 8, an upper alignment of the window WN or the first gap G1 by which the window protection film PL extends beyond the second edge WN_E may be confirmed (or controlled) in the transmissive area TA, which is formed by the light blocking pattern BM being recessed from the first edge PL_E of the window protection film PL. For example, as illustrated in depiction (b) of FIG. 8, a lower alignment of the window WN or the first gap G1 by which the window protection film PL extends beyond the second edge WN_E may be confirmed (or controlled) in the transmissive area TA, which is formed by the light blocking pattern BM being recessed from the lower surface of the window protection film PL.

That is, as illustrated in FIGS. 6 and 8, the alignment of the window WN along an axis in the second direction DR2 (e.g., y-axis) or the extension distance of the window protection film PL along an axis in the second direction DR2 (e.g., y-axis) may be visually confirmed through the upper and lower defined transmissive areas TA3 and TA4.

In an embodiment of the present disclosure, the display device DD may include the window protection film PL arranged on the window WN and including the light blocking pattern BM. The light blocking pattern BM may extend along the first edge PL_E of the window protection film PL, may be recessed at least partially on each surface of the window protection film PL to define the transmissive area TA. Since the alignment of the window WN or the extension distance of the window protection film PL may be visibly confirmed through the transmissive area TA, display quality of the display device DD may be improved.

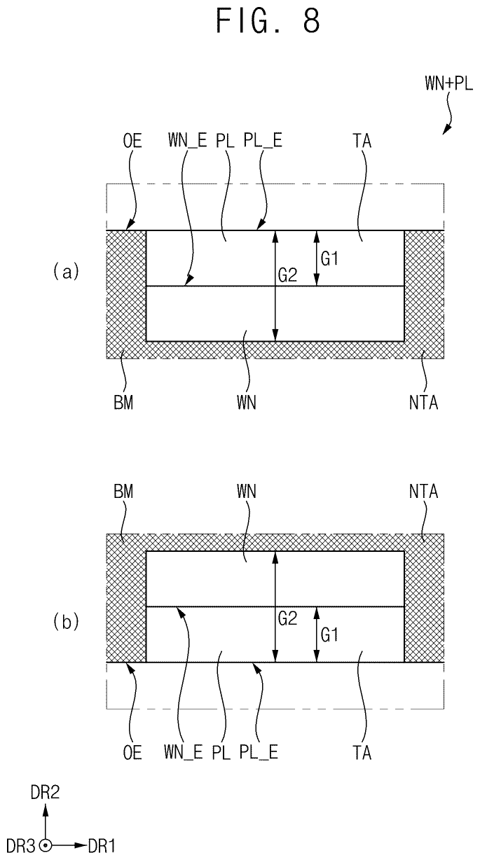

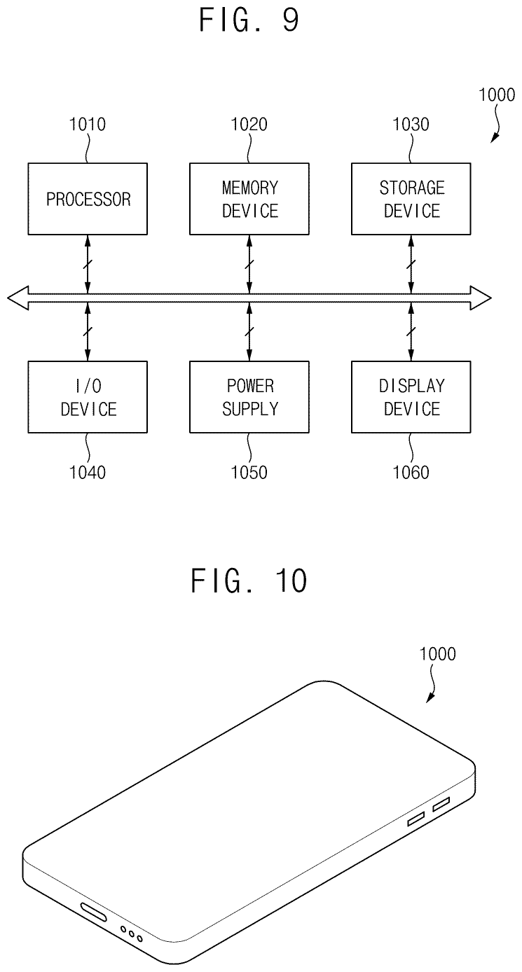

FIG. 9 is a block diagram illustrating an electronic device according to an embodiment of the present disclosure. FIG. 10 is a diagram illustrating an example in which the electronic device of FIG. 9 is implemented as a smartphone.

Referring to FIGS. 9 and 10, an electronic device 1000 may include a processor 1010, a memory device 1020, a storage device 1030, an input/output (I/O) device 1040, a power supply 1050, and a display device 1060. The display device 1060 may be the above-described display device DD. The electronic device 1000 may further include a plurality of ports for communicating with a video card, a sound card, a memory card, a universal serial bus (USB) device, other systems, or the like.

In an embodiment, as illustrated in FIG. 10, the electronic device 1000 may be implemented as a smartphone. However, this is exemplary, and the electronic device 1000 is not limited thereto. For example, the electronic device 1000 may be implemented as a cellular phone, a video phone, a television, a smart pad, a smart watch, a tablet PC, a vehicle display, a computer monitor, a laptop, a head mounted display (HMD), or the like.

The processor 1010 may perform various computing functions. The processor may control the display device 1060. The processor 1010 may be a microprocessor, a central processing unit (CPU), an application processor (AP), or the like. The processor 1010 may be coupled to other components through an address bus, a control bus, a data bus, or the like. In an embodiment, the processor 1010 may be coupled to an extended bus such as a peripheral component interconnection (PCI) bus.

The memory device 1020 may store data for operations of the electronic device 1000. For example, the memory device 1020 may include at least one non-volatile memory device such as an erasable programmable read-only memory (EPROM) device, an electrically erasable programmable read-only memory (EEPROM) device, a flash memory device, a phase change random access memory (PRAM) device, a resistance random access memory (RRAM) device, a nano floating gate memory (NFGM) device, a polymer random access memory (PoRAM) device, a magnetic random access memory (MRAM) device, a ferroelectric random access memory (FRAM) device, or the like and/or at least one volatile memory device such as a dynamic random access memory (DRAM) device, a static random access memory (SRAM) device, a mobile DRAM device, or the like.

The storage device 1030 may include a solid-state drive (SSD) device, a hard disk drive (HDD) device, a CD-ROM device, or the like. The I/O device 1040 may include an input device such as a keyboard, a keypad, a mouse device, a touch-pad, a touch-screen, or the like, and an output device such as a printer, a speaker, or the like.

The power supply 1050 may provide power for operations of the electronic device 1000. The display device 1060 may be connected to other components through buses or other communication links. In an embodiment, the display device 1060 may be included in the I/O device 1040.

The present disclosure can be applied to various display devices and electronic devices. For example, the present disclosure is applicable to various display devices such as display devices for vehicles, ships and aircraft, portable communication devices, display devices for exhibition or information transmission, medical display devices, and the like.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A window protection film comprising:
an edge including a side surface;
a main surface that is connected to the edge and is in a plane that makes an angle with the side surface; and
a light blocking pattern on the main surface, the light blocking pattern extending along the edge and flush with the side surface, the light blocking pattern having a non-transmissive area and a transmissive area.

2. The window protection film of claim 1, wherein the main surface includes:
a first side;
a second side facing the first side;
a third side connected to each of the first side and the second side; and
a fourth side facing the third side and connected to each of the first side and the second side.

3. The window protection film of claim 2, wherein the transmissive area comprises a first transmissive area, a second transmissive area, a third transmissive area, and a fourth transmissive area,
the first transmissive area is disposed along the first side and flush with the side surface;
the second transmissive area is disposed along the second side and flush with the side surface;
the third transmissive area is disposed along the third side and flush with the side surface; and
the fourth transmissive area is disposed along the fourth side and flush with the side surface.

4. The window protection film of claim 3, wherein the first transmissive area and the second transmissive area face each other.

5. The window protection film of claim 3, wherein the third transmissive area and the fourth transmissive area face each other.

6. A display device comprising:
a display panel including a plurality of pixels;
a window arranged on the display panel; and
a window protection film arranged on the window and including:
a first edge having a side surface;
a main surface that is connected to the first edge and is in a plane that forms an angle with the side surface; and
a light blocking pattern on the main surface, the light blocking pattern extending along the first edge and flush with the side surface, the light blocking pattern having a non-transmissive area and a transmissive area.

7. The display device of claim 6, wherein the first edge of the window protection film extends beyond a second edge of the window by a first gap.

8. The display device of claim 7, wherein the main surface includes:
a first side;
a second side facing the first side;
a third side connected to each of the first side and the second side; and
a fourth side facing the third side and connected to each of the first side and the second side.

9. The display device of claim 8, the transmissive area includes:
a first transmissive area disposed along the first side and flush with the side surface;
a second transmissive area disposed along the second side and flush with the side surface;
a third transmissive area disposed along the third side and flush with the side surface; and
a fourth transmissive area disposed along the fourth side and flush with the side surface.

10. The display device of claim 9, wherein each of the first transmissive area, the second transmissive area, the third transmissive area, and the fourth transmissive area have a width that is greater than the first gap, measured from the first edge.

11. The display device of claim 9, wherein the second edge of the window is visible through each of the first transmissive area, the second transmissive area, the third transmissive area, and the fourth transmissive area.

12. The display device of claim 9, wherein the first transmissive area and the second transmissive area face each other.

13. The display device of claim 9, wherein:
the first transmissive area is at a midpoint of the first side, and
the second transmissive area is at a midpoint of the second side.

14. The display device of claim 9, wherein the third transmissive area and the fourth transmissive area face each other.

15. The display device of claim 9, wherein:
the third transmissive area is at a midpoint of the third side, and
the fourth transmissive area is at a midpoint of the fourth side.

16. The display device of claim 6, wherein the window includes ultra-thin glass (UTG).

17. The display device of claim 6, wherein the display device includes:
a folding area having flexibility; and
a non-folding area adjacent to at least one side of the folding area.

18. An electronic device comprising:
a display device including:
a display panel including a plurality of pixels;
a window arranged on the display panel; and
a window protection film arranged on the window; and
a processor that controls the display device,
wherein the window protection film includes:
a first edge including a side surface;
a main surface connected to the first edge and is in a plane that makes an angle with the side surface; and
a light blocking pattern on the main surface, the light blocking pattern extending along the first edge and flush with the side surface, the light blocking pattern having a non-transmissive area and a transmissive area.

19. The electronic device of claim 18, wherein:
the first edge of the window protective film extends beyond a second edge of the window by a first gap,
the transmissive area of the light blocking pattern is flush with the side surface and has a width that is greater than the first gap measured from the first edge.

20. The electronic device of claim 19, wherein the second edge of the window is visible through the transmissive area.
